(19) United States
(12) Patent Application Publication
(10) Pub. No.: US 2002/0112964 A1
(43) Pub. Date: Aug. 22, 2002

(54) Process window for gap-fill on very high aspect ratio structures using additives in low acid copper baths

(75) Inventors: Srinivas Gandikota, Santa Clara, CA (US); Chris McGuirk, San Jose, CA (US); Deenesh Padhi, San Jose, CA (US); Sivakami Ramanathan, Fremont, CA (US); Girish Dixit, San Jose, CA (US)

Correspondence Address: Patent Counsel, APPLIED MATERIALS, INC., P.O. Box 450A, Santa Clara, CA, 95052, US

(73) Assignee: Applied Materials, Inc.

(21) Appl. No.: 10/109,560

(22) Filed: Mar. 26, 2002

Related U.S. Application Data
(63) Continuation-in-part of application No. 09/615,038, filed on Jul. 12, 2000.

(51) Int. Cl. C25D 5/02; H01L 21/288; H01L 21/445; C25D 3/00; C25D 3/38

(52) U.S. Cl. 205/118; 205/123; 205/261; 205/291

(57) ABSTRACT

The present invention provides a composition and method for void-free plating of a metal into high aspect ratio features. The plating process is carried out in a plating solution containing metal at a molar concentration of between about 0.4 M and about 0.9 M, an acid at a concentration of between about 4 mg/L and about 40 mg/L, a suppressor at a concentration of between about 2 mL/L and about 15 mL/L, an accelerator at a concentration of between about 1.5 mL/L and about 8 mL/L, and a leveler at a concentration of between about 4 mL/L and about 11 mL/L.

### CROSS-REFERENCE TO RELATED APPLICATIONS

This application is a continuation-in-part of co-pending U.S. patent application Ser. No. 09/615,038 filed Jul. 12, 2000, which is incorporated herein by reference.

### BACKGROUND OF THE INVENTION

1. Field of the Invention

Embodiments of the present invention generally relate to defect-free filling of features on a substrate with copper. More particularly, embodiments of the present invention relate to an electroplating composition and method for filling features formed on substrates.

2. Description of the Related Art

Electroplating processes for manufacturing semiconductor devices typically require a thin, continuous, electrically conductive seed layer to be deposited on a substrate prior to the plating process. The seed layer generally is formed of a conductive metal, such as copper, and is conventionally deposited on the substrate using PVD or CVD techniques. Electroplating a desired metal is then generally accomplished by applying an electrical bias to the seed layer and exposing the substrate to an electroplating solution containing metal ions that will plate over the seed layer in the presence of the electrical bias.

Copper has a lower resistivity, e.g., 1.7 μΩ-cm compared to 3.1 μΩ-cm for aluminum, and can carry a higher current density than aluminum. Therefore, it is desirable to use copper to form interconnects in semiconductor devices, rather than aluminum. The electroplating solutions used in many conventional plating cells are designed to provide acceptable plating results when used in many different cell designs, on many different substrates, and in numerous different applications, such as electroplating and mechanical polishing. Typically, electroplating solutions consist of copper sulfate solutions including sulfuric acid to change the acidity or pH of the plating solution, copper chloride for nucleation of suppressor molecules, and additives to aid in depositing copper on the surface of a substrate and in filling submicron sized features, e.g., vias and interconnects. The additives may include any combination of, but not limited to, levelers, brighteners or accelerators, inhibitors, suppressors, enhancers, and surfactants. The additives are typically organic molecules that adsorb onto the surface of the substrate. Certain additives may decrease the ionization rate of metal atoms, thereby inhibiting the deposition process, whereas other additives may increase the dissolution rate of removed metal ions, thereby increasing the deposition rate of metal.

Cells which are not specifically designed to provide highly uniform current density and the deposit thickness distribution on specific substrates, e.g., substrates of varying diameter, utilize high conductivity solutions to provide high throwing power, e.g., a high Wagner number, so that good coverage is achieved on all surfaces of the plated substrate. As used herein, “throwing power” refers to the ability of a plating solution to deposit metal uniformly on a substrate. An acid, such as sulfuric acid, or occasionally a conductive salt, is added to the electroplating solution to provide the high ionic conductivity to the plating solution necessary to achieve high throwing power. The acid does not participate in the electrode reactions, but is required in order to provide conformal coverage of the plating material over the surface of the object because the acid reduces the resistivity within the electroplating solution.

A problem encountered with conventional plating solutions is that the deposition process on small features is controlled by mass transport, i.e., diffusion, of the metal into the features and by the kinetics of the electrolyte reaction instead of by the magnitude of the electric field as is common on large features. Therefore, the rate at which plating ions are provided to the surface of the substrate can limit the plating rate, irrespective of the voltage or current density applied to the plating surface. Hence, highly conductive electroplating solutions that provide conventional throwing power have little significance in obtaining good coverage and fill within a relatively small feature, i.e., sub-micron sized, because the transport rates are diminished by approximately one half, which may cause a reduction in the quality of the deposit and may lead to fill defects, particularly on small features. In order to obtain good quality deposition, the deposition process must have high mass-transfer rates and low depletion of the reactant concentration near or within the small features. However, in the presence of excess acid, the transport rates are diminished.

Diffusion of the metal ion to be plated is directly related to the concentration of the plated metal ion in the electroplating solution. A higher metal ion concentration results in a higher rate of diffusion of the metal into small features and in a higher metal ion concentration within the depletion layer, i.e., the boundary layer, at the cathode surface, hence faster and better quality deposition may be achieved.

Although electrochemical deposition of copper can be achieved by pulse plating using two component chemistries, i.e., electroplating solutions including accelerators and suppressors, pulse plating on a non-continuous seed layer leads to erosion of the seed layer at regions of minimal coverage. As a result, most systems use three component chemistries, ie., suppressors, accelerators, and levelers. Suppressors inhibit or reduce copper deposition in the adsorbed areas, while accelerators accumulate growth in the adsorbed areas. One problem encountered as a result of this competition for adsorption sites is that the accelerator may accumulate at the mouth of the feature, e.g., via/trench, and close the mouth of the feature before the feature is completely filled, thus creating a void. Another problem is that various parameters such as temperature, electrode voltage, and acidity of the solution affect the desired ability of the suppressers and accelerators to provide bottom up coverage of a feature.

Therefore, there exists a need for a composition and method for plating a metal in small features, e.g., sub-micron scale and smaller features.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof, which are illustrated in the appended drawing. It is to be noted, however, that the appended drawing illustrates only typical embodiments of this invention, and is therefore, not to be considered limiting of its scope, for the invention may admit to other equally effective embodiments.

FIG. 1 is a cross-sectional view of an exemplary electroplating system of the invention.

### SUMMARY OF THE INVENTION

Embodiments of the invention generally provide a method and composition for plating a metal into high aspect ratio features. The method includes disposing the substrate and an anode in a plating solution, the solution having metal ions at a molar concentration of between about 0.4 M and about 0.9 M, an acid at a concentration of between about 4 gm/L and about 40 gm/L, a suppressor at a concentration of between about 2 mL/L and about 15 mL/L, an accelerator at a concentration of between about 1.5 mL/L and about 8 mL/L, and a leveler at a concentration of between about 4 mL/L and about 11 mL/L. The metal ions are then plated from the plating solution into the features without forming voids within features on the substrate.

Embodiments of the invention further provide a composition for plating a metal into high aspect ratio features. The composition includes metal ions at a molar concentration of between about 0.4 M and about 0.9 M, a suppressor at a concentration of between about 2 mL/L and about 15 mL/L, an accelerator at a concentration of between about 1.5 mL/L and about 8 mL/L, and a leveler at a concentration of between about 4 mL/L and about 11 mL/L.

Embodiments of the invention also provide a method for plating copper into high aspect ratio features. The method generally includes disposing a substrate and an anode in a plating solution, the solution having copper ions at a molar concentration of between about 0.6 M and about 0.9 M, chlorine at a concentration of between about 30 ppm and about 60 ppm, sulfuric acid at a concentration of between about 4 gm/L and about 10 gm/L, a suppressor at a concentration of between about 3.5 mL/L and about 12 mL/L, an accelerator at a concentration of between about 2.5 mL/L and about 5.5 mL/L, and a leveler at a concentration of between about 4 mL/L and about 11 mL/L. The method further includes plating copper ions from the plating solution into the features.

### DETAILED DESCRIPTION OF THE PREFERRED EMBODIMENT

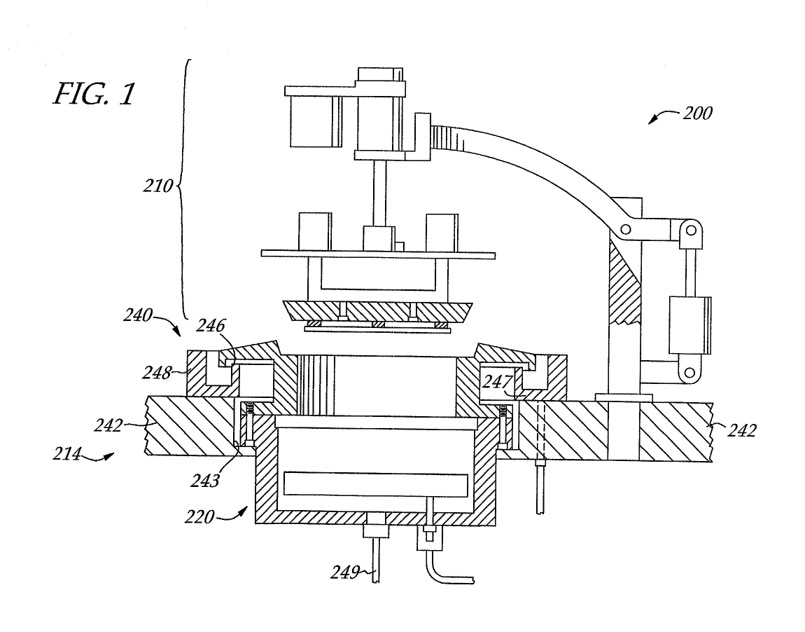

FIG. 1 illustrates a cross sectional view of an exemplary electroplating cell of the present invention. The exemplary processing cell 100 generally includes a head assembly 110, a process kit 120, and an electroplating solution collector 140. The electroplating solution collector 140 may be secured onto the body 142 of the mainframe 114 over an opening 143 that defines a location for placement of the process kit 120. The electroplating solution collector 140 generally includes an inner wall 146, an outer wall 148, and a bottom 147 connecting the respective walls. A fluid inlet 149 may be disposed through the bottom of the electroplating solution collector 140 wherein electroplating solution may enter the electroplating cell.

Embodiments of the invention employ aqueous copper plating solutions comprising copper sulfate at a concentration of between about 30 g/L and about 55 g/L, i.e., between about 0.48 M and about 0.9 M. An electroplating solution having a high copper concentration, i.e., greater than 0.4 M, is beneficial to overcome mass transport limitations that are encountered when plating small features. In particular, because sub-micron scale features with high aspect ratios, i.e., greater than 4:1, typically allow only minimal or no electroplating solution flow therein, the ionic transport relies solely on diffusion to deposit metal into the small features. A high copper concentration in the electroplating solution, typically in the range of about 0.4 M to about 0.9 M, and preferably from about 0.6 M to about 0.9 M, enhances the diffusion process and reduces or eliminates the mass transport limitations. The metal concentration required for the plating process may depend on other factors such as temperature and the acid concentration of the electroplating solution. A lower acid concentration often permits the use of a higher metal ion, e.g., copper sulfate, concentration due to elimination of the limiting effect of the acid. Additionally, the diffusion of metal ions in the electroplating solution is dependent on temperature, e.g., as temperature increases, diffusion increases. Therefore, the operating temperatures of the electroplating solution may range from about 15° C. to about 25° C. In addition to copper sulfate, the electroplating solution may include other copper salts, such as copper fluoborate, copper gluconate, copper sulfamate, copper sulfonate, copper pyrophosphate, copper chloride, or copper cyanide. Some of these salts offer higher solubility than copper sulfate and therefore may be advantageous.

In embodiments of the present invention, a high sulfuric acid concentration may be detrimental to uniform plating because the resistive substrate effects may be amplified by a highly conductive electroplating solution. The effects may be amplified because the degree of uniformity of the current distribution and the corresponding deposit thickness is dependent on the ratio of the resistance the current flow within the electroplating solution to the resistance of the substrate. Therefore, when uniformity is a primary concern, it is desirable to have a high resistance within the electroplating solution. Since the electroplating solution resistance is equal to 1/KTTr², it is advantageous to have a low conductivity, K. As used herein, TT is approximately equal to 3.14, r is equal to the radius of the substrate, and K is equal to the conductivity of the electroplating solution. Therefore, the electroplating solution includes an acid at a concentration of between about 4 gm/L and about 60 gm/L.

The plating solution may also contain halide ions, such as chloride ions at a concentration of between about 10 ppm and about 80 ppm. The plating solution may further includes suppressors, accelerators, and levelers to assist in filling small features. Suppressors generally adsorb on the substrate surface and inhibit or reduce copper deposition in the adsorbed areas. Suppressors added to the plating solution may include two-element polyethylene glycol based suppressors, such as suppressors made of random/block copolymers of ethylene oxide and propylene oxide mixed in a wide range of ratios. Accelerators compete with suppressers for adsorption sites and accelerate copper growth in the adsorbed areas. The accelerators used in the plating solution may include sulphur containing compounds, such as sulfite or di-sulfate. Accelerators, with smaller molecular dimensions, can diffuse faster than suppressors. Suppressors and accelerators heavily populate around the features and since the suppressors inhibit the copper growth, a small overhang of the seed layer can close the mouth of the feature leading to a void in the feature. Therefore, the most desired electroplating solution is one where the suppression is mostly active on the top of the topographical features and the accelerators dominate the suppressors in activity inside features so as to achieve bottom up growth. Therefore, embodiments of the invention include an electroplating solution having an accelerator concentration of between about 2.5 mL/L and about 8 mL/L, a suppressor concentration of between about 2 mL/L and 12 mL/L, and a leveler concentration of between about 2 mL/L and about 11 mL/L.

An exemplary embodiment of the invention is described below. A substrate with a patterned dielectric layer of Si/SiO₂ thereon, receives a conformal TaN barrier layer having a thickness of about 250 Å deposited using a Vectra IMP source, which is commercially available from Applied Materials, Inc., of Santa Clara, Calif., using process conditions recommended by the equipment manufacturer. A PVD Cu seed layer having a thickness of about 500 Å to about 1000 Å is then deposited on the TaN barrier layer using an Electra Cu source, which is also commercially available from Applied Materials, Inc., of Santa Clara, Calif., using process conditions recommended by the equipment manufacturer.

The plating process may be carried out on the Electra ECP system, which is commercially available from Applied Materials, Inc., of Santa Clara, Calif. The temperature of the plating solution may be about 20° C. The additives, accelerator “X” and suppresser “Y”, for example, may be supplied by Enthone OMI, of New Haven, Conn. Scanning electron microscope (SEM) and focused ion beam (FIB) techniques may be used to study the feature fill.

The activity of suppressers and accelerators depends on various parameters such as temperature, pH of the plating solution, and chloride concentration in the electroplating solution. The temperature effect of the activities of the additives is related to the polarization dependence of these additives on temperature. The temperature at which one can achieve void free fill is expected to be different for different plating solution compositions and different additives in the plating solution. An exemplary embodiment of the invention includes a plating solution having chlorine ions at a concentration of about 50 ppm, copper ions at a concentration of between about 35 g/L and about 50 g/L, and an acid at a concentration of about 50 gm/L. The plating solution further includes suppressors at a concentration of about 3 mL/L, accelerators at a concentration of about 6.5 mL/L, and levelers at a concentration of about 4 mL/L.

The addition of suppressors and accelerators improves the control of the deposition rates of electroplating solutions. Since the suppressors and accelerators tend to fill the features as soon as the substrate comes into contact with the plating solution, any delay between the substrate immersion into the plating solution and the start of actual plating may lead to voiding in the features due to random distribution of the additives and the etching of the seed layer. To reduce such voiding activity, a substrate loading bias from about −0.8 V to about −10 V may be applied to the substrate plating surface while the substrate is being immersed in the plating solution. While theoretical calculations of electrochemical chemical potential establish a loading bias of −0.32 V, the experimental data collected shows otherwise. Experimental data indicated that applying a loading bias of about −0.8 V or greater for 200 mm substrates provided a void free fill of the features. For plating 300 mm substrates, an immersion loading bias of about −2 V to about −8 V yields void free fill. The results additionally indicate that loading bias not only circumvents seed layer dissolution but also provide polarization of organic molecules conducive for superfill.

To further enhance plating, the substrate is rotated upon immersion into the plating solution between about 20 rpm and about 50 rpm. Upon plating, the substrate is rotated between about 3 rpm and about 30 rpm. Exemplary embodiments of the invention rotate the substrate upon immersion at about 30 rpm and upon plating at about 5 rpm.

It has been observed that at current densities greater than about 20 mA/cm², copper deposits rapidly, not allowing establishment of a concentration gradient of organic molecules. At current densities less than about 1 mA/cm², suppressors overpopulate in the features, resulting in seams. Therefore, the plating process of the embodiments described herein are carried out at current densities ranging between about 1 mA/cm² and about 20 mA/cm², preferably between about 1 mA/cm² and about 7.5 mA/cm². An exemplary embodiment of the invention applies a current density of about 60 mA/cm² for bottom fill of the features and a current density of 10 mA/cm² for the plating step.

Embodiments of the invention are described in reference to electroplating copper on substrates. However, it is to be understood that low conductivity electroplating solutions, particularly solutions having low acid concentrations, can be used to deposit metals other than copper on resistive substrates and have application in any field where plating can be used to advantage.

While the foregoing is directed to the preferred embodiment of the present invention, other and further embodiments of the invention may be devised without departing from the basic scope thereof, and the scope thereof is determined by the claims that follow.

What is claimed is:

1. A method for plating a metal into high aspect ratio features, comprising:
disposing a substrate and an anode in a plating solution, the solution comprising:
metal ions at a molar concentration of between about 0.4 M and about 0.9 M;
an acid at a concentration of between about 4 gm/L and about 60 gm/L;
a suppressor at a concentration of between about 2 mL/L and about 15 mL/L;
an accelerator at a concentration of between about 1.5 mL/L and about 8 mL/L;
a leveler at a concentration of between about 2 mL/L and about 11 mL/L; and
plating metal ions from the plating solution into the features.

3. The method of claim 1, wherein the plating solution is at a temperature of between about 15° C. and about 25° C.

4. The method of claim 1, wherein metal ions are at a molar concentration of between about 0.6 M and about 0.9 M.

5. The method of claim 1, wherein the metal ions are copper ions.

6. The method of claim 1, wherein the suppressor is at a concentration of between about 3.5 mL/L and about 12 mL/L.

7. The method of claim 1, wherein the suppressor comprises a mixture selected from the group comprising polyethylene glycols, copolymers of ethylene oxide, and copolymers of propylene oxide.

8. The method of claim 1, wherein the accelerator is at a concentration of between about 2.5 mL/L and about 5.5 mL/L.

9. The method of claim 1, wherein the accelerator is a sulphur containing compound selected from the group comprising sulfite and di-sulfate.

10. The method of claim 1, wherein the leveler is at a concentration of between about 4 mL/L and about 11 mL/L.

11. The method of claim 1, further comprising biasing the substrate with a loading bias of between about −0.8 V and about −10 V during a loading process.

12. The method of claim 1, wherein the substrate is 300 mm in diameter

13. The method of claim 12, further comprising biasing the substrate with a loading bias between about −2 V and about −8 V.

14. The method of claim 1, wherein the plating solution contains halide ions.

15. The method of claim 1, wherein the plating solution contains chlorine at a concentration of between about 10 ppm and about 80 ppm.

16. The method of claim 1, wherein the plating solution contains chlorine at a concentration of between about 30 ppm and about 60 ppm.

17. The method of claim 1, wherein the substrate is biased with a current density of between about 1 mA/cm² and about 20 mA/cm² during the plating step.

18. The method of claim 1, wherein the acid is at a concentration of between about 4 gm/L and about 10 gm/L.

19. The method of claim 1, wherein the acid is sulfuric acid at a concentration of between about 4 gm/L and about 10 gm/L.

20. The method of claim 1, wherein the plating solution comprises:
copper sulfate at a molar concentration of between about 0.6 M and about 0.9 M;
chlorine at a concentration of between about 30 ppm and about 60 ppm;
sulfuric acid at a concentration of between about 4 gm/L and about 10 gm/L;
the suppressor at a concentration of between about 3.5 mL/L and about 12 mL/L;
the accelerator at a concentration of between about 2.5 mL/L and about 5.5 mL/L; and
the leveler at a concentration of between about 4 mL/L and about 11 mL/L.

21. An electroplating solution for plating a metal into high aspect ratio apertures, comprising:
metal ions at a molar concentration of between about 0.4 M and about 0.9 M;
an acid at a concentration of between about 4 gm/L and about 60 gm/L;
a suppressor at a concentration of between about 2 mL/L and about 15 mL/L;
an accelerator at a concentration of between about 1.5 mL/L and about 8 mL/L; and
a leveler at a concentration of between about 2 mL/L and about 11 mL/L.

22. The plating solution of claim 21, wherein the metal ions are at a molar concentration of between about 0.6 M and about 0.9 M.

23. The plating solution of claim 21, wherein the metal ions are copper ions.

24. The plating solution of claim 21, wherein the suppressor is at a concentration of between about 3.5 mL/L and about 12 mL/L.

25. The plating solution of claim 21, wherein the accelerator is at a concentration of between about 2.5 mL/L and about 5.5 mL/L.

26. The plating solution of claim 21, wherein the leveler is at a concentration from of between 4 mL/L and about 11 mL/L.

27. The plating solution of claim 21, wherein the solution comprises:
copper ions at a molar concentration of between about 0.6 M and about 0.9 M;
chlorine ions at a concentration of between about 30 ppm and about 60 ppm;
the suppressor at a concentration of between about 3.5 mL/L and about 12 mL/L;
the accelerator at a concentration of between about 2.5 mL/L and about 5.5 mL/L of; and
the leveler at a concentration of between about 4 mL/L and about 11 mL/L.

28. A method for plating copper into high aspect ratio features, comprising:
disposing a substrate and an anode in a plating solution, the solution comprising:
copper ions at a molar concentration of between about 0.6 M and about 0.9 M;
chlorine at a concentration of between about 30 ppm and about 60 ppm;
sulfuric acid at a concentration of between about 4 gm/L and about 10 gm/L;
a suppressor at a concentration of between about 3.5 mL/L and about 12 mL/L;
an accelerator at a concentration of between about 2.5 mL/L and about 5.5 mL/L; and
a leveler at a concentration of between about 4 mL/L and about 11 mL/L; and
plating copper ions from the plating solution into the features.

29. The method of claim 28, wherein the plating solution is at a temperature of between about 15° C. and about 25° C.

30. The method of claim 28, further comprising biasing the substrate with a loading bias of between about −0.8 V and about −10 V.

31. The method of claim 28, wherein the substrate is biased with a current density of between about 1 mA/cm² and about 20 mA/cm² during the plating step.
